(19) United States
(12) Patent Application Publication
(10) Pub. No.: US 2006/0038285 A1
(43) Pub. Date: Feb. 23, 2006

(54) Electronic apparatus

(75) Inventors: Hideshi Tokuhira, Kawasaki (JP); Hiroaki Date, Kawasaki (JP); Hiroki Uchida, Kawasaki (JP); Minoru Ishinabe, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 10/991,395

(22) Filed: Nov. 19, 2004

(30) Foreign Application Priority Data
Aug. 23, 2004 (JP) 2004-242631

(51) Int. Cl. H01L 23/34

(52) U.S. Cl. 257/714

(57) ABSTRACT

A small-size and light-weight electronic apparatus with a cooling structure capable of exhibiting good cooling performance is provided. A cover member with a plurality of grooves for forming a channel is joined by brazing to a housing on a lid body side to which an LCD panel is attached, and these grooves are covered with the housing to form a channel for circulating a coolant. The housing constitutes a part of the channel, and the channel for the coolant is integrated into the housing. Heat generated by a main body is transferred to the lid body side by the coolant and dissipated outside through the housing that performs the function of a heat-radiation plate.

### CROSS-REFERENCE TO RELATED APPLICATION

This non-provisional application claims priority under 35 U.S.C. §119(a) on Patent Application No. 2004-242631 filed in Japan on Aug. 23, 2004, the entire contents of which are hereby incorporated by reference.

### BACKGROUND OF THE INVENTION

The present invention relates to an electronic apparatus that radiates heat by using a circulating coolant.

Electronic apparatuses such as desktop computers, notebook computers, and mobile communication apparatuses have microprocessors (MPU). With the recent advances in the processing speed, functionality and performance of microprocessors, the amount of heat generated during operation is increasing. In order to keep stable operations of the microprocessors, it is necessary to enhance the radiation performance by quickly discharging the generated heat out of the apparatuses.

Therefore, electronic apparatuses are generally equipped with an air-cooling type cooling device for cooling the microprocessor. The cooling device comprises a heat sink for absorbing the heat generated by the microprocessor and dissipating the heat, and a cooling fan for sending cool air to the heat sink. As described above, since it is predicted that the amount of heat generated by microprocessors will continue to increase in the future, it is necessary to take measures to cope with this situation.

In order to improve the cooling performance, air-cooling type cooling devices take measures, such as enlarging the heat sink and improving the performance of the cooling fan. However, the use of a large heat sink causes a problem that the size of the electronic apparatus is also increased to incorporate the large heat sink. On the other hand, in order to improve the performance of the cooling fan, it is necessary to enlarge the fan structure or increase the rotation speed of the cooling fan, and thus this measure has a problem that an increase in the size of the electronic apparatus or an increase in fan noise is unavoidable. In particular, for notebook computers, the portability, namely the size and weight of the apparatus are important as well as the cooling performance, and silence, that is, quietness during operation, is an important element. However, the above-mentioned measures to improve the cooling performance conflict with these important elements.

Hence, liquid-cooling type cooling systems using a liquid such as water having much higher specific heat than the air as a refrigerant were proposed (for example, Japanese Patent Applications Laid-Open Nos. 2003-124670, 2003-303034, and 2003-316476).

FIG. 1 is a cross sectional view showing the cooling structure of a conventional electronic apparatus (notebook computer) disclosed in Japanese Patent Application Laid-Open No. 2003-124670. In FIG. 1, the reference numeral 51 represents an LCD (Liquid Crystal Display) panel which is fixed and supported on a housing 52 on the LCD side. In the housing 52, a heat-radiation plate 53 is disposed to face the LCD panel 51, and a stainless radiation pipe 54 as a channel in which a coolant flows is provided on an opposing surface of the heat-radiation plate 53 to the LCD panel 51. The radiation pipe 54 extends to the main body (not shown) of the electronic apparatus that generates heat.

The cooling structure of FIG. 1 performs the cooling function by natural radiation by transferring the heat generated by the main body (not shown) of the electronic apparatus to the heat-radiation plate 53 disposed on the LCD side. The heat generated by the main body (not shown) is transferred by a coolant circulating in the radiation pipe 54, and dissipated outside through the heat-radiation plate 53 and the housing 52.

In the cooling structure shown in FIG. 1, since the cooling process is performed without using a cooling fan, there is no problem of fan noise during cooling. However, since the heat-radiation plate 53 and radiation pipe 54 for cooling are additionally required, the thickness of the housing 52 on the LCD side increases, and consequently an increase in the overall size of the electronic apparatus is unavoidable, and there is also a problem of an increase in the weight. Moreover, in the cooling structure shown in FIG. 1, since the heat is dissipated through the pipe wall of the radiation pipe 54 and the heat-radiation plate 53, there is a problem of poor cooling efficiency.

### BRIEF SUMMARY OF THE INVENTION

The present invention has been made with the aim of solving the above problems, and it is an object of the present invention to provide a small-size and light-weight electronic apparatus having a cooling structure capable of exhibiting good cooling performance.

An electronic apparatus according to a first aspect of the invention is an electronic apparatus comprising: a main body that generates heat; and a lid body for covering the main body, wherein the heat generated by the main body is discharged outside by a coolant, and the lid body constitutes a part of a channel for the coolant.

An electronic apparatus according to a second aspect of the invention is based on the first aspect, wherein the channel is formed by joining a cover member in which a plurality of grooves are formed and the lid body.

An electronic apparatus according to a third aspect of the invention is based on the first aspect, wherein the channel is formed by joining the lid body in which a plurality of grooves are formed and a cover member in the form of a flat plate.

An electronic apparatus according to a fourth aspect of the invention is based on any one of the first through third aspects, wherein the lid body is made of a material selected from the group consisting of aluminum, magnesium and copper.

In the present invention, the lid body for covering the main body that generates heat constitutes a part of the coolant channel, that is, the coolant channel is integrated into the lid body. Radiation of heat is performed by transferring the heat generated by the main body to the lid body side by the coolant and circulating the heat in the channel integrated into the lid body. The lid body performs the function of a heat-radiation plate. Thus, since there is no need to use a heat-radiation plate and a radiation pipe as in the conventional example, it is possible to achieve a small-size and light-weight electronic apparatus. Moreover, since the lid body constitutes a part of the coolant channel, the thermal resistance is smaller compared to the conventional example, and consequently the cooling efficiency is improved.

In the present invention, in order to form such a channel, the cover member in which a plurality of grooves are formed and the lid body are joined, or the lid body in which a plurality of grooves are formed and the cover member in the form of a flat plate are joined. Thus, the channel integrated into the lid body is easily formed.

As the material for the lid body, aluminum, magnesium or copper is used. Therefore, the lid body that performs the function of a radiation plate has high thermal conductivity and good heat-radiation characteristics.

The above and further objects and features of the invention will more fully be apparent from the following detailed description with accompanying drawings.

### BRIEF DESCRIPTION OF THE SEVERAL VIEWS OF THE DRAWINGS

FIG. 1 is a cross sectional view showing the cooling structure of a conventional electronic apparatus;

FIG. 2 is a perspective view showing an electronic apparatus of the present invention;

FIG. 3 is a plan view showing one example (the first embodiment) of the cooling structure of the electronic apparatus of the present invention;

FIG. 4 is a cross sectional view showing one example (the first embodiment) of the cooling structure of the electronic apparatus of the present invention;

FIGS. 5A through 5C are cross sectional views showing the steps in the process of forming a channel;

FIG. 6 is a cross sectional view showing the cooling structure of an electronic apparatus of a comparative example; and

FIG. 7 is a cross sectional view showing another example (the second embodiment) of the cooling structure of the electronic apparatus of the present invention.

### DETAILED DESCRIPTION OF THE INVENTION

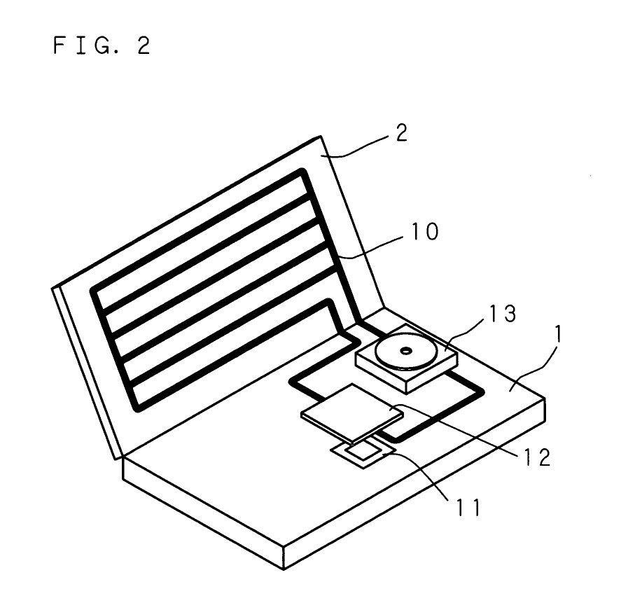

The following description will explain in detail the present invention, based on the drawings illustrating some embodiments thereof. FIG. 2 is a perspective view showing an electronic apparatus of the present invention. This electronic apparatus is a notebook computer, for example, but an illustration of the LCD panel is omitted in FIG. 2.

In FIG. 2, the electronic apparatus of the present invention comprises a housing 1 on the main body side (hereinafter referred to as the first housing 1), and a housing 2 on the lid body side (hereinafter referred to as the second housing 2). In the first housing 1 and second housing 2, a channel 10 (the part shown by the thick line in FIG. 2) for circulating a coolant such as water is formed.

In the first housing 1, the channel 10 is positioned in the vicinity of an MPU element 11 that generates an especially large amount of heat. A heat receiving plate 12 is provided for the MPU element 11 so as to transfer the heat generated by the MPU element 11 to the coolant in the channel 10 through the heat receiving plate 12. A pump 13 is disposed on the way of the channel 10 in the first housing 10, and the coolant is circulated in the channel 10 when the pump 13 is driven.

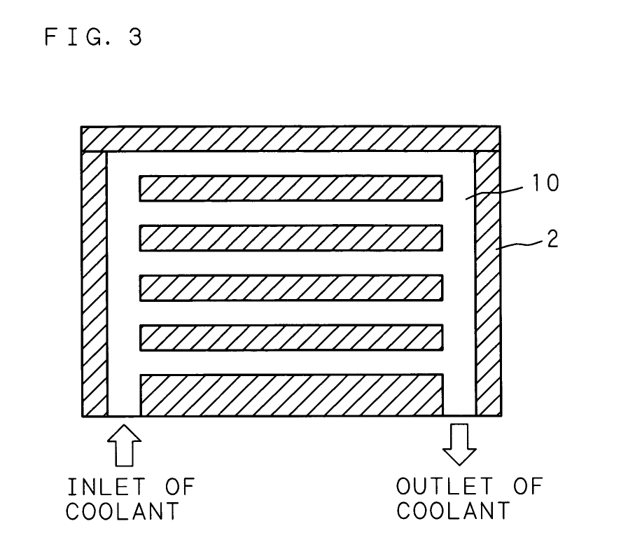

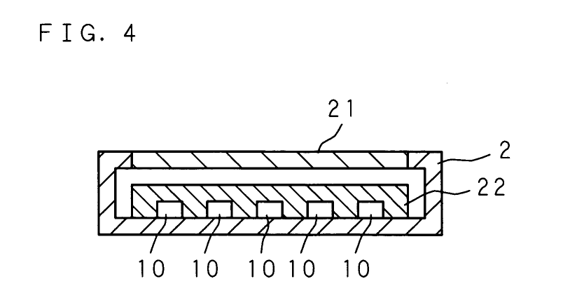

The structure of the channel 10 in the second housing 2, which is the characteristic feature of the present invention, will be described in detail. FIG. 3 and FIG. 4 are a plan view and a cross sectional view showing one example (the first embodiment) of the cooling structure of the electronic apparatus of the present invention.

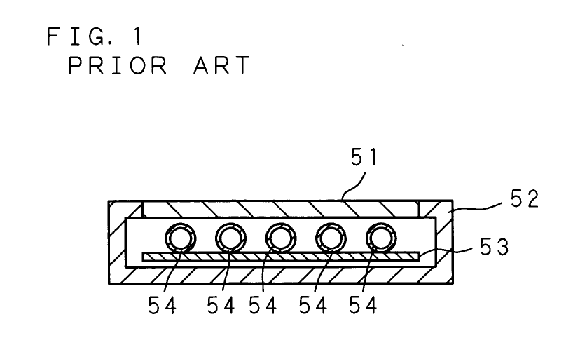

An LCD panel 21 is attached to the second housing 2 (thickness: 0.7 mm) made of aluminum. An aluminum cover member 22 (thickness: 0.7 mm) with a plurality of grooves for forming a channel is joined to the second housing 2 by brazing, and these grooves are covered with the second housing 2 so as to form the channel 10. In other words, in the present invention, the second housing 2 constitutes a part of the coolant channel 10, and the coolant channel 10 is integrated into the second housing 2. In the present invention, since the channel 10 is formed so that it is integrated into the second housing 2, the heat-radiation plate 53 and the radiation pipe 54 which are used in the conventional example (FIG. 1) are not required, thereby making the overall structure of the second housing 2 thinner compared to the conventional example. As a result, it is possible to achieve a small-size and light-weight electronic apparatus.

The heat generated by the main body, particularly the MPU element 11, is transferred to the lid body side by the coolant circulating in the channel 10, and dissipated outside through the second housing 2 that performs the function of a heat-radiation plate. In the present invention, only the second housing 2 has a thermal resistance, and therefore the present invention has small thermal resistance and good radiation characteristics compared to the conventional example (FIG. 1) in which the pipe wall of the radiation pipe 54 and the heat-radiation plate 53 have thermal resistance. Moreover, compared to the conventional example (FIG. 1) which has poor thermal conductivity because the radiation pipe 54 and the heat-radiation plate 53 are in point contact with each other, the present invention has good thermal conductivity because the channel 10 and the second housing 2 are in surface contact with each other. Thus, according to the present invention, the cooling efficiency is much improved compared to the conventional example (FIG. 1).

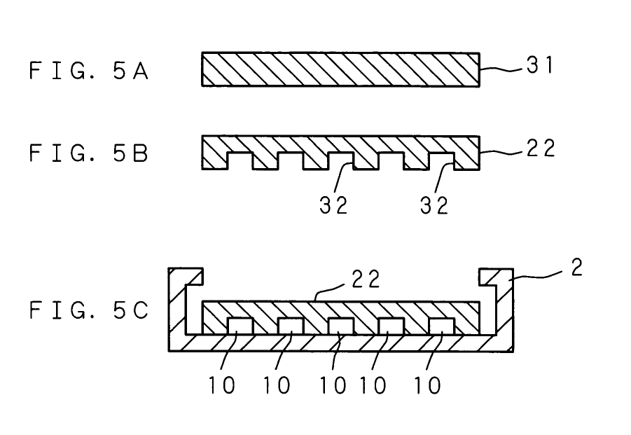

Next, the following description will explain the process of forming the channel 10 in the lid body. FIG. 5A through FIG. 5C are cross sectional views showing the steps in the process of forming the channel 10. An aluminum flat plate 31 is prepared (FIG. 5A), and a plurality of grooves 32 are formed by performing press work on the flat plate 31, so as to produce the cover member 22 (FIG. 5B). The channel 10 is formed by joining the second housing 2 and the cover member 22 by brazing (FIG. 5C).

In the above-described example, although the second housing 2 and the cover member 22 are joined by brazing, it may also be possible to join the second housing 2 and the cover member 22 with an adhesive. In this case, an adhesive is applied in advance to the joint face of the flat plate 31 and/or the joint face of the second housing 2, and then the second housing 2 and the cover member 22 are joined by applying pressure and heat to them.

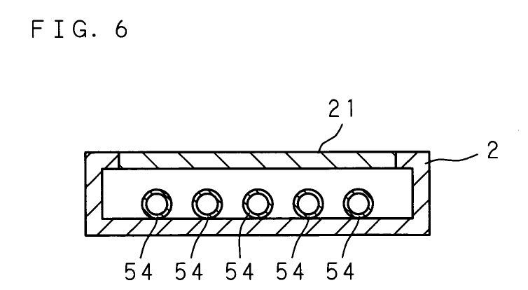

Next, the following description will explain the results of a cooling evaluation test performed on the above-mentioned cooling structure of the present invention (first embodiment). Note that a cooling structure as shown in FIG. 6 was produced as a comparative example, and the same cooling evaluation test was also performed on this comparative example. The comparative example shown in FIG. 6 has a structure in which a radiation pipe 54 similar to the conventional example (FIG. 1) is directly mounted on the second housing 2 similar to the present invention. However, the heat-radiation plate 53 used in the conventional example (FIG. 1) is not mounted.

The conditions for the cooling evaluation tests performed on the first embodiment and the comparative example which have exactly the same structures except for the cooling structure on the lid body side are as follows. The cooling treatment was performed by setting the output of the MPU element 11 to 30 W, and the temperature in the vicinity of the MPU element 11 was measured. In the first embodiment, the measured value of the temperature was 67° C., and thus this embodiment satisfied standardized thermal design values of not higher than 70° C. On the other hand, in the comparative example, the measured value was 72° C., and thus this example could not satisfy the standardized thermal design values of not higher than 70° C.

The reason for this is that the comparative example has poor cooling performance compared to the first embodiment because the thermal resistance of the radiation pipe 54 and the thermal resistance between the radiation pipe 54 and the second housing 2 are large, and the radiation pipe 54 and the second housing 2 are in point contact with each other. On the other hand, in the first embodiment, since the thermal resistance is small and the channel 10 and the second housing 2 are in surface contact with each other, good cooling performance is exhibited.

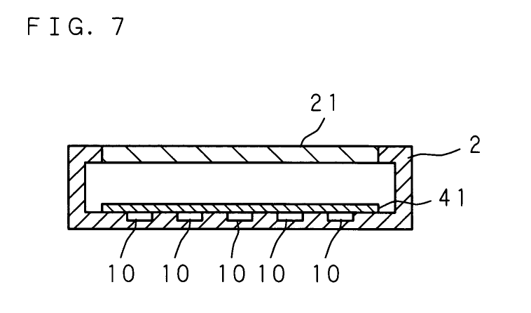

Next, another embodiment of the present invention will be explained. FIG. 7 is a cross sectional view showing another example (the second embodiment) of the cooling structure of the electronic apparatus of the present invention. In FIG. 7, the same parts as in FIG. 4 are designated with the same numbers.

In the second embodiment, the channel 10 is produced by forming a plurality of grooves in the aluminum second housing 2 (thickness: 1.0 mm) and covering these grooves with a cover member 41 made of an aluminum flat plate for forming the channel 10. In this example, the second housing 2 also constitutes a part of the coolant channel 10, and the coolant channel 10 is integrated into the second housing 2. Therefore, the second embodiment produces the same effects as the above-mentioned first embodiment.

A cooling evaluation test was performed on the second embodiment under the same conditions as in the above-mentioned first embodiment and comparative example. As a result, the measured value of the temperature was 67° C., and thus, similarly to the first embodiment, the second embodiment satisfied the standardized thermal design values of not higher than 70° C.

Note that in the above-mentioned embodiments, although aluminum is used as a material of the second housing 2, it may also be possible to use other metals such as magnesium and copper. For the material of the second housing 2, high thermal conductivity is required to cause the second housing 2 to function as a heat-radiation plate, and also a light weight is required to decrease the weight. It is preferable to consider the importance of these requirements when determining a material to be used for the second housing 2.

Moreover, in the above-mentioned embodiments, although aluminum is used as a material of the cover members 22 and 41 for forming the channel, it may also be possible to use other metals such as magnesium and copper, or resins. According to the present invention, when great importance is attached to dissipation of heat to the second housing 2 side instead of the cover member 22 or 41 side, a material having an insulating property is preferred.

As described above, in the present invention, since the lid body for covering the main body that generates heat constitutes a part of the coolant channel, it is possible to provide an electronic apparatus having a cooling structure capable of realizing good cooling efficiency, without causing an increase in the size and weight.

Furthermore, in the present invention, since the coolant channel is formed by joining the cover member in which a plurality of grooves are formed and the lid body, or joining the lid body in which a plurality of grooves are formed and the cover member in the form of a flat plate, the channel integrated into the lid body can be easily formed.

Additionally, in the present invention, since aluminum, magnesium or copper is used as a material for the lid body that performs the function of a heat-radiation plate, it is possible to obtain good radiation characteristics.

As this invention may be embodied in several forms without departing from the spirit of essential characteristics thereof, the present embodiments are therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1. An electronic apparatus comprising:
a main body that generates heat; and
a lid body for covering the main body,
wherein the heat generated by the main body is discharged outside by a coolant, and
the lid body constitutes a part of a channel for the coolant.

2. The electronic apparatus of claim 1, wherein
the lid body is made of a material selected from the group consisting of aluminum, magnesium and copper.

3. The electronic apparatus of claim 1, wherein
the channel is formed by joining a cover member in which a plurality of grooves are formed and the lid body.

4. The electronic apparatus of claim 3, wherein
the cover member and the lid body are joined by brazing or an adhesive.

5. The electronic apparatus of claim 3, wherein
the cover member is made of a material selected from the group consisting of aluminum, magnesium, copper and resins.

6. The electronic apparatus of claim 1, wherein
the channel is formed by joining the lid body in which a plurality of grooves are formed and a cover member in the form of a flat plate.

7. The electronic apparatus of claim 6, wherein
the cover member and the lid body are joined by brazing or an adhesive.

8. The electronic apparatus of claim 6, wherein
the cover member is made of a material selected from the group consisting of aluminum, magnesium, copper and resins.
